(19) United States
(12) Patent Application Publication
(10) Pub. No.: US 2024/0120289 A1
(43) Pub. Date: Apr. 11, 2024

(54) ELECTRONIC PACKAGE AND A METHOD FOR MAKING THE SAME

(71) Applicant: JCET STATS ChipPAC Korea Limited, Incheon (KR)

(72) Inventors: SeungHyun LEE, Incheon (KR); YeJin PARK, Incheon (KR); HeeSoo LEE, Incheon (KR)

(21) Appl. No.: 18/475,249

(22) Filed: Sep. 27, 2023

(30) Foreign Application Priority Data
Oct. 11, 2022 (CN) 202211241165.9

(51) Int. Cl. H01L 23/552; H01L 23/00; H01L 23/498; H01L 23/66; H01L 25/065

(52) U.S. Cl. CPC H01L 23/552; H01L 23/49838; H01L 23/66; H01L 24/16; H01L 24/32; H01L 25/0655; H01L 2223/6616; H01L 2223/6644; H01L 2223/6677; H01L 2224/16155; H01L 2224/16225; H01L 2224/32146; H01L 2224/32225; H01L 2924/142; H01L 2924/1431; H01L 2924/182; H01L 2924/3025

(57) ABSTRACT

An electronic package is provided. The electronic package comprises a substrate having a first region and a second region; a first set of electronic components mounted on the substrate in the first region; a second set of electronic components mounted on the substrate in the second region; an encapsulant layer disposed on the substrate and encapsulating the first and second sets of electronic components; a set of interconnect components disposed on the substrate in the second region, and extending through the encapsulant layer, wherein the set of interconnect components are electrically coupled to the first and second sets of electronic components; and a connector mounted on the encapsulant layer and electrically coupled to the first and second sets of electronic components through the set of interconnect components.

### TECHNICAL FIELD

The present application generally relates to semiconductor technology, and more particularly, to an electronic package and a method for making an electronic package.

### BACKGROUND OF THE INVENTION

In recent years, wireless communication using millimeter-wave signals (e.g., with a frequency of 24 to 60 gigahertz (GHz) or higher) is facing challenges as electronic packages are generally dictated by cost, size, weight and performance. Therefore, 5G antenna-in-package (AIP) with a system and an antenna integrated into one package has been adopted for mobile handsets or other portable multimedia devices. However, this 5G AIP requires reduced more pins, reduced thickness, and higher integration.

Therefore, a need exists for a process for making an electronic package with improved integration.

### SUMMARY OF THE INVENTION

An objective of the present application is to provide a method for making an electronic package with improved integration.

According to an aspect of the present application, an electronic package is provided. The electronic package comprises a substrate having a first region and a second region; a first set of electronic components mounted on the substrate in the first region; a second set of electronic components mounted on the substrate in the second region; an encapsulant layer disposed on the substrate and encapsulating the first and second sets of electronic components; a set of interconnect components disposed on the substrate in the second region, and extending through the encapsulant layer, wherein the set of interconnect components are electrically coupled to the first and second sets of electronic components; and a connector mounted on the encapsulant layer and electrically coupled to the first and second sets of electronic components through the set of interconnect components.

According to a further aspect of the present application, a method for making an electronic package is provided. The method comprises: providing a substrate having a first region and a second region; mounting a first set of electronic components on the substrate in the first region; mounting a second set of electronic components on the substrate in the second region; mounting a set of interconnect components on the substrate in the second region; forming an encapsulant layer on the substrate to encapsulate the first and second sets of electronic components and the set of interconnect components; forming a set of openings through the encapsulant layer to expose the set of interconnect components, respectively; mounting a connector on the interconnect components, wherein the connector has a set of terminals that are aligned with the set of openings respectively, such that the connector is electrically coupled to the first and second sets of electronic components through the set of interconnect components.

It is to be understood that both the foregoing general description and the following detailed description are exemplary and explanatory only and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a perspective view of a conventional electronic package 100.

FIG. 2 illustrates a cross-sectional view of an electronic package 200 according to an embodiment of the present application.

FIGS. 3A to 3J are cross-sectional views illustrating various steps of a method for making an electronic package according to an embodiment of the present application.

FIG. 4A illustrates a perspective view of an electronic package 400 according to an embodiment of the present application.

FIG. 4B illustrates a perspective view of the electronic package 400 as shown in FIG. 4A with its connector removed.

FIGS. 5 and 6 illustrate top views of electronic package 500 and 600 according to some other embodiments of the present application.

FIG. 7 is a flowchart illustrating a method for making an electronic package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

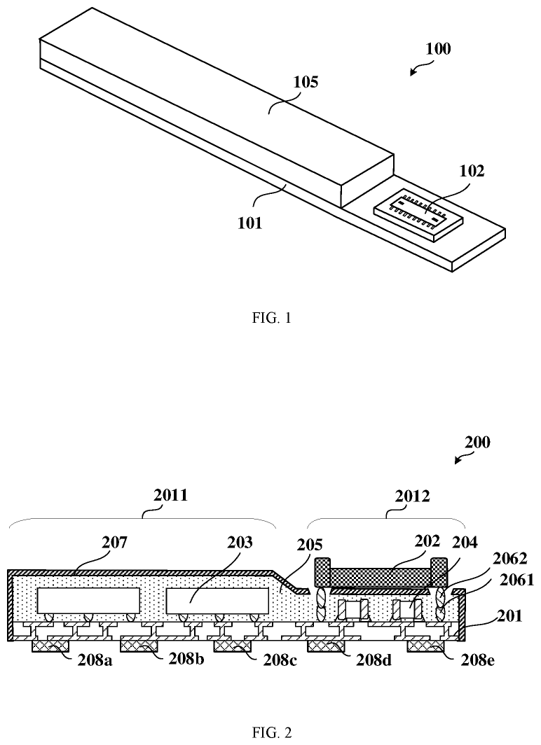

FIG. 1 illustrates a conventional electronic package 100. As shown in FIG. 1, the electronic package 100 includes a substrate 101 and a plurality of electronic components (not shown) mounted on the substrate 101. An encapsulant layer 105 is formed over the substrate 101 to encapsulate the plurality of electronic components. The electronic package 100 also includes a connector 102 such as a board-to-board connector, which is mounted on the substrate 101 and electrically coupled with the other electronic components encapsulated by the encapsulant layer 105 via interconnect structures inside the substrate 101. The connector 102 is used for electrically coupling the electronic package 100 with other electronic devices outside the electronic package 100.

As shown in FIG. 1, the connector 102 and the plurality of electronic components are disposed side by side on the substrate 101, which may occupy a relatively big space that may not be applicable for an advanced electronic system such as a smartphone. In order to address the above issue, the inventors of the present application conceived a new design of electronic packages where a connector can be stacked over some smaller electronic components that are mounted on a substrate, which can reduce the size of the electronic package and make the electronic package more compact.

FIG. 2 illustrates a cross-sectional view of an electronic package 200 according to an embodiment of the present application.

As shown in FIG. 2, the electronic package 200 includes a substrate 201. In some embodiments, the substrate 201 may be a printed circuit board (PCB) and may include a redistribution structure (RDS) having one or more dielectric layers and one or more conductive layers between and through the dielectric layers. The conductive layers may define pads, traces, and plugs through which electrical signals or voltages can be distributed horizontally and vertically across the RDS. In some embodiments, the RDS may include a plurality of conductive patterns formed on both or either of the top and bottom surfaces of the substrate 201.

A plurality of electronic components is mounted on the substrate 201. In some embodiments, the plurality of electronic components may include one or more semiconductor dices, semiconductor devices and/or discrete devices. For example, the electronic components may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. The electronic components may also be passive devices such as capacitors, inductors, or resistors.

In the embodiment shown in FIG. 2, the plurality of electronic components includes a first set of electronic components 203 and a second set of electronic components 204, both of which are encapsulated by an encapsulant layer 205. In particular, the substrate 201 includes a first region 2011 and a second region 2012. The first set of electronic components 203 are mounted on the substrate 201 in the first region 2011, while the second set of electronic components 204 are mounted on the substrate 201 in the second region 2012. In the example, the first set of electronic components 203 may include two active devices such as an RF integrated circuit (IC) chip and a power management IC chip which have bigger form factors, and the second set of electronic components 204 may include two passive devices such as capacitors, which have smaller form factors. Since the first set of electronic components 203 are higher than the second set of electronic components 204, a portion of the encapsulant layer 205 in the first region 2011 may be thicker than the other portion of the encapsulant layer 205 in the second region 2012. In addition, a transition region between the first region 2011 and the second region 2012 may be formed on the substrate, which may include a slope or a step in the encapsulant layer 205.

As aforementioned, the encapsulant layer 205 may have a thickness in the first region 2011 greater than that in the second region 2012. Thus, a gap may be formed over the encapsulant layer 205 in the second region 2012, which provides for a space for accommodating and mounting a connector 202 such as a board-to-board connector over the second set of electronic components 204. As shown in FIG. 2, a set of interconnect components 206 are mounted on the substrate 201 in the second region 2012, which extend through the encapsulant layer 205 from the top surface of the substrate 201 substantially to the top surface of the encapsulant layer 205. Specifically, the set of interconnect components 206 may include a first set of interconnect components 2061 and a second set of interconnect components 2062. The first set of interconnect components 2061 are formed around the second set of electronic components 204 and in contact with the substrate 201. Furthermore, the second set of interconnect components 2062 are stacked on the first set of interconnect components 2061, respectively, and exposed from the encapsulant layer 205 in the second region 2012. Both the first set of interconnect components 2061 and the second set of interconnect components 2062 are electrically coupled to the first sets of electronic components 203 and the second sets of electronic components 204 via the interconnect structures inside the substrate 201, to allow for electrical connection between the connector 202 and the electronic components on the substrate 201. In the embodiment, the heights of the interconnect components 206 are higher than the second set of electronic components 204, because it may be desired that the interconnect components 206 extend through the encapsulant layer 205 thereby a connector can be mounted on the electronic package and connected to the interconnect components 206.

The set of interconnect components 206 are made of conductive materials, e.g., solder balls, conductive pillars, copper pillars, conductive balls or copper balls, but aspects of the present disclosure are not limited thereto. Although the interconnect components 206 are presented as solder balls in the example shown in FIG. 2, there can be other examples where one or more of the solder balls may be other conductive balls, or conductive pillars, or conductive posts, for example. The set of interconnect components 206 are disposed around the second set of electronic components 204 in any proper arrangements. In the example shown in FIG. 2, the solder balls are arranged in an oval arrangement when viewed from the top of the substrate 201. In some embodiments, the interconnect components 206 may include one or more of Sn, Ni, Al, Cu, Au, Ag, or other suitable electrically conductive material. The first set of interconnect components 2061 and the second set of interconnect components 2062 can be made of the same material or different materials.

Still referring to FIG. 2, the connector 202 is electrically coupled to the first set of electronic components 203 and the second set of electronic components 204 through the set of interconnect components 206 and the interconnect structures inside the substrate 201. In particular, a set of openings in the encapsulant layer 205 can be formed by laser ablation, where the first set of interconnect components 2061 can be exposed after the laser ablation, and then the second set of interconnect components 2062 are bonded to the first set of interconnect components 2061. The connector 202 includes a set of terminals, which are aligned with the second set of interconnect components 2062, respectively. That is, the layout or arrangement of the interconnect components 206 may be identical to that of the terminals of the connector 202. In this way, when placed on the substrate 201, the connector 202 can be electrically coupled to the first set of electronic components 203 and the second set of electronic components 204. In some embodiments, the number of the interconnect components can be determined based on the number of the terminals of the connector.

Furthermore, the electronic package 200 may further include a shielding layer 207 which generally covers the encapsulant layer 205. In some embodiments, a set of openings are further formed in the shielding layer 207, being aligned with and corresponding to the set of openings in the encapsulant layer 205. As such, the set of interconnect components 206 can extend through the encapsulant layer 205 and the shielding layer 207 to allow for connection with the connector 202. It can be appreciated that the openings in the shielding layer 207 are sufficiently big that the shielding layer 207 may not be in contact with any of the interconnect components 206. In some embodiments, the shielding layer 207 may be one or more layers of Al, Cu, Sn, Ni, Au, Ag, or other suitable conductive material. In some embodiments, the shielding layer 207 may be carbonyl iron, stainless steel, nickel silver, low-carbon steel, silicon-iron steel, foil, conductive resin, carbon-black, aluminum flake, or other metals and conductive materials capable of reducing the influence of EMI, RFI, and other inter-device interference.

In addition, the electronic package 200 may also include a plurality of antenna modules such as patch antenna, which can be embedded at the back side of the substrate 201 (not shown). In some embodiments, the plurality of antenna modules can be formed in the substrate 201 with other conductive layers within the substrate 201. Furthermore, as shown in FIG. 2, a plurality of dielectric members 208 (208a, 208b, 208c, 208d, 208e) are disposed on the backside surface of substrate 201 and close to the plurality of antenna modules, respectively, to improve the radio-frequency (RF) signal communication of the plurality of antenna modules. In particular, the dielectric members 208 (208a, 208b, 208c, 208d, 208e) may increase an oblique angle transmission and reception area of the plurality of antenna modules. In addition, the RF signal incident into the dielectric member 208 may be refracted according to dielectric constant Dk of the dielectric members 208, which improves a transmission and reception rate or a gain of the antenna modules. In some embodiments, each of dielectric members 208 may have a hemisphere shape, a semi-elliptical shape, a lens shape, or a rectangular shape. The shape of dielectric members may be varied according to optimization of refraction/diffraction/reflection characteristics of the RF signal, a height standard, structural adhesion stability, and other characteristics. As shown in FIG. 2, the dielectric members 208 (208a, 208b, 208c, 208d, 208e) are presented as rectangular shapes, but aspects of the present disclosure are not limited thereto.

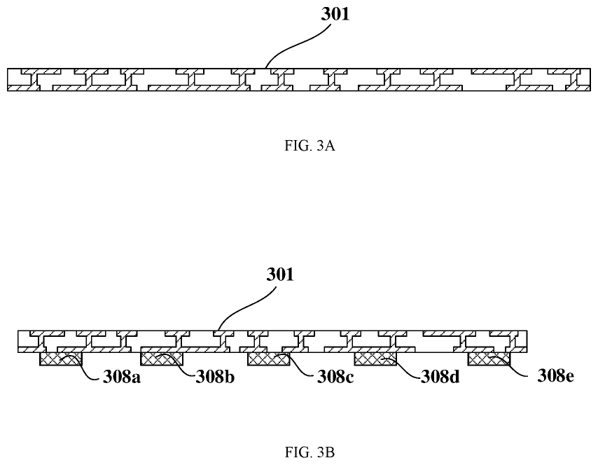

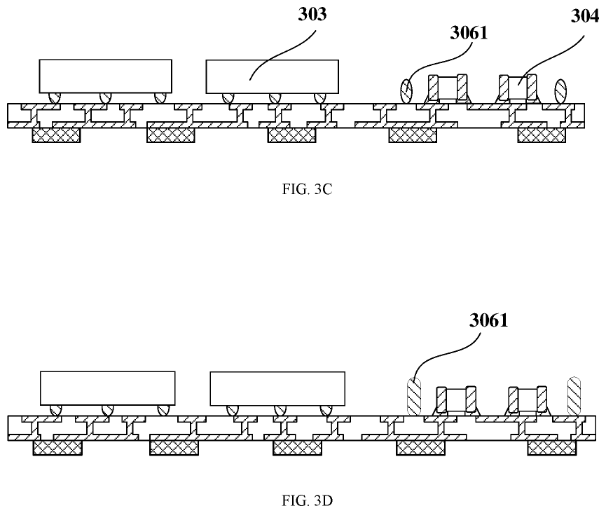

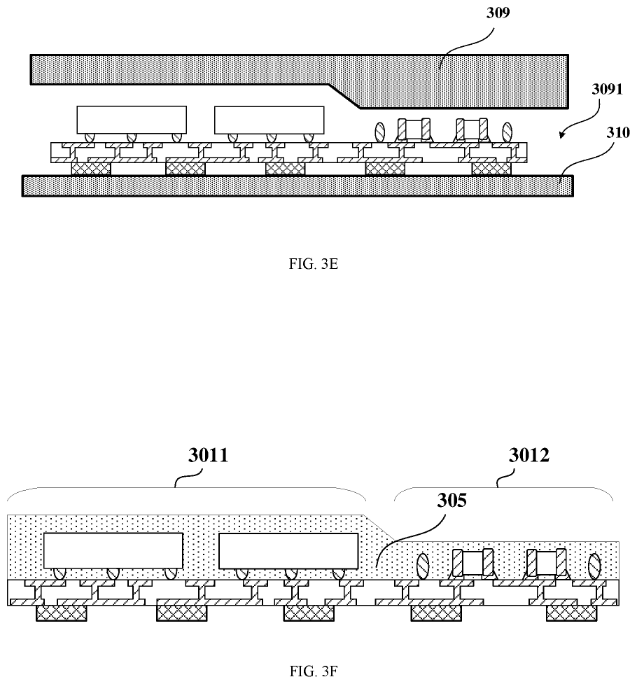

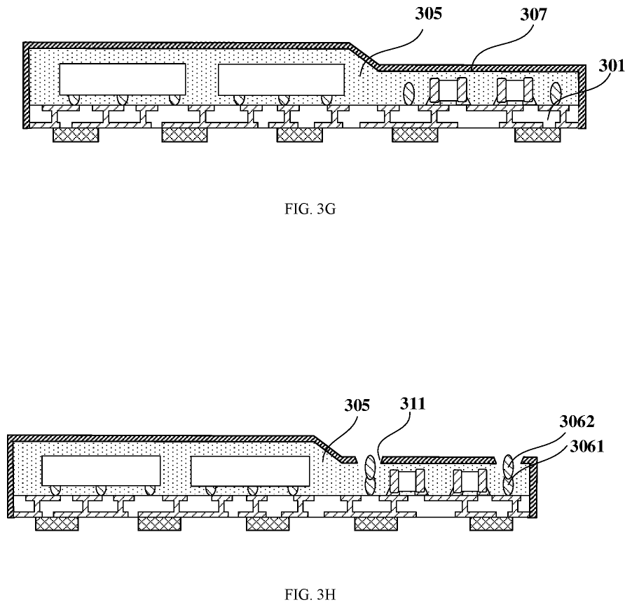

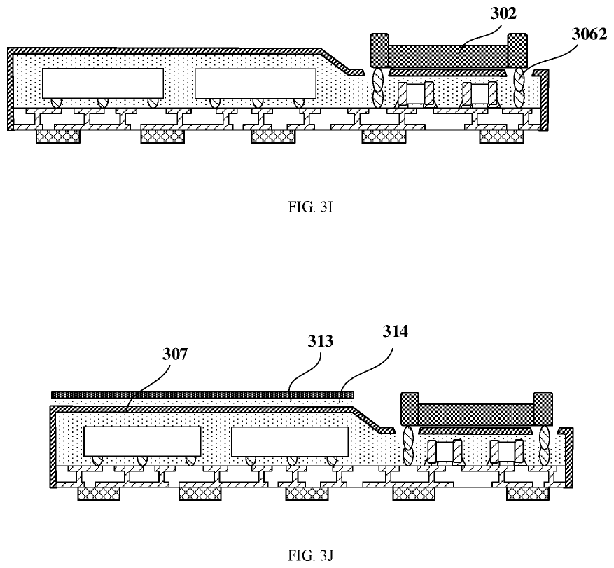

Referring to FIGS. 3A to 3J, various step of a method 300 for making an electronic package is illustrated according to an embodiment of the present application. For example, the method 300 may be used to make the electronic package 200 shown in FIG. 2. In the following, the method will be described with reference to FIGS. 3A to 3J in more details.

As shown in FIG. 3A, a substrate 301 is provided. Afterwards, with reference to FIG. 3B, a plurality of antenna modules, such as patch antenna (not shown) are embedded on the back side of the substrate 301, and a plurality of dielectric members 308a, 308b, 308c, 308d and 308e are formed on the plurality of antenna modules. In some embodiments, each of dielectric members may be formed by cutting a dielectric block, a curing process for injecting a dielectric powder into a mold or a middle cutting by dielectric lens. In some embodiments, the dielectric members may be formed of a material having a high dielectric constant Dk such as Ajinomoto build-up film (ABF), epoxy molding compound (EMC), poly propylene glycol (PPG), glass, ceramic, silicon, Copper Clad Laminate (CCL), quartz, and Teflon.

As shown in FIG. 3C, a plurality of electronic components including a first set of electronic components 303 and a second set of electronic components 304 are mounted on the front side of the substrate 301. The first set of electronic components 303 are higher than the second set of electronic components 304. Then, a first set of solder balls 3061 are disposed around the second set of electronic components 304, which have a smaller height than the second set of electronic components 304. Alternatively, the first set of solder balls 3061 can be replaced by conductive pillars as shown in FIG. 3D or other suitable conductive structures.

As shown in FIG. 3E, after the first set of solder balls are formed on the substrate, an encapsulant layer can be formed to encapsulant the substrate and various components disposed thereon. In particular, the electronic package can be placed between the bottom mold chase 310 and a top mold chase 309. It can be appreciated that the sidewalls of the mold chases 309 and 310 are not shown. A chamber is thus formed between the bottom mold chase 309 and the top mold chase 310, where the molding process for the encapsulant layer can be performed. The top mold case 309 may be pressed against the bottom mold chase 310 to form a molding cavity 3091, for example, through clamping to avoid relative movement of the substrate 301 between the top mold chase 309 and the bottom mold chase 310. An encapsulant material can be injected into the molding cavity 3091 under proper temperature and pressure to form the encapsulant layer on the substrate. And the encapsulant material is then cured and solidified to form the encapsulant layer 305 as shown in FIG. 3F, for example, in a thermal curing process. It can be appreciated that the portion of the encapsulant layer 305 in the first region 3011 is thicker than the other portion of the encapsulant layer 305 in the second region 3012, so that the electronic components can be properly protected by the encapsulant layer 305.

With reference to FIG. 3G, a shielding layer 307 which is a conformal EMI shielding layer is formed on the encapsulant layer 305, which prevents electromagnetic noises radiated by or transmitted to high-frequency devices in the electronic package. In particular, the EMI shielding layer 307 is formed to cover the encapsulant layer 305 and extend down to the sidewalls of the substrate 301. In some embodiments, the shielding layer 307 may be formed using sputtering or other suitable metal deposition processes.

Afterwards, referring to FIG. 3H, a set of openings 311 corresponding to the first set of solder balls 3061 are formed by laser ablation in the portion of the encapsulant layer 305 within the second region 3012. And then additional conductive fillers, such as a second set of solder balls 3062 are filled within the set of openings 311 respectively, to elevate the set of interconnect components 306 to substantially above the encapsulant layer 305 and the EMI shielding layer 307. Specifically, each of the openings 311 can be ablated as a bowl-shaped recess which is recessed from the top surface of the encapsulant layer 305 into certain distance within the encapsulant layer 305. The recess should be wide enough for the insertion of the second set of solder balls 3062 into the openings 311 but undesired connection between the second set of solder balls 3062 and the EMI shielding layer 307 can be avoided. It can be appreciated that the openings 311 can be formed with other alternative shapes, such as a trapezoid shape. In some embodiments, the recess is wide enough so that there is a gap between the exposed portion of the second set of solder balls 3062 and the sidewall of each opening. In some alternative embodiments, the openings 311 can be formed by etching, mechanical drilling, or any other suitable techniques. After inserted into the openings, the second set of solder balls 3062 may be bonded with the first set of respective solder ball 3061 through a reflow process, for example.

As shown in FIG. 3I, a connector 302 is mounted in the first region over the encapsulant layer 305, and a set of terminals of the connector 302 are aligned with the second set of solder balls 3062, respectively. After a reflow process, the connector 302 can be secured with the solder balls 3062, being a part of the electronic package.

In some optional embodiments, a heat dissipation lid to transfer heat from the electronic package to a surrounding environment may be desired. As shown in FIG. 3J, a heat dissipation lid 313 can be attached on the EMI shielding layer 307 in the first region 3011 for heat dissipation and a conductive material 314 can be applied between the heat dissipation lid 313 and the EMI shielding layer 307, which later can be solidified as a thermally interface layer 314.

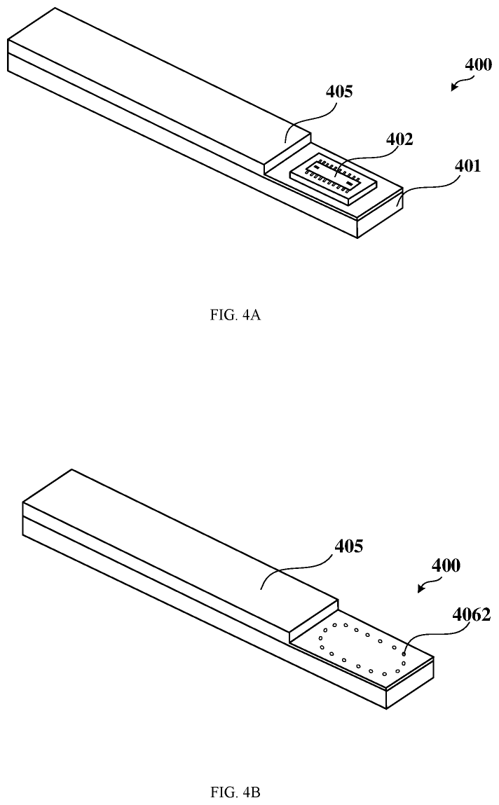

FIG. 4A illustrates perspective views of an electronic package 400 according to an embodiment of the present application, while as shown in FIG. 4B, a connector of the electronic package 400 is removed for ease of illustration. It can be seen from FIG. 4A that, compared with the electronic package 100 shown in FIG. 1, the size of the electronic package 400 is much smaller after the connector 402 is stacked on a portion of electronic components mounted on a substrate 401, because the connector 402 does not occupy additional footprint on the substrate 401. Also, the overall height of the electronic package 400 is also generally not increased because the connector 402 generally flushes with an encapsulant layer 405 besides it. It can be appreciated that the connector 402 may be slightly higher than the top surface of the encapsulant layer 405 if a certain type of connector with a greater thickness is selected, however, at least a portion of the connector 402 can be embedded within the encapsulant layer 405.

FIG. 4B illustrates the perspective view of the electronic package 400 before attaching the connector on the substrate. It can be seen that a second set of solder balls 4062 or other similar interconnect components are exposed from the encapsulant layer 405 in a second region of the substrate. The arrangement of the second set of solder balls 4062 may be identical to that of the terminals of the connector.

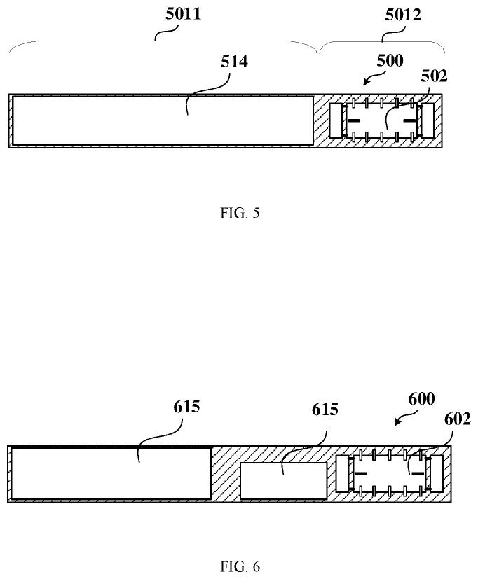

In some embodiments, especially when the electronic packages include high-power electronic components such as power circuit IC chips, a lot of heat may be generated during operation, especially at the high-power consumption electronic components. Thus, proper heat dissipation means such as heat dissipation lids may be desired for the electronic packages. FIGS. 5 and 6 illustrate top views of electronic packages 500 and 600 according to some other embodiments of the present application.

As shown in FIG. 5, a heat dissipation lid 514 is attached on an encapsulant layer of the electronic package 500 in a first region 5011 for heating dissipation. The heat dissipation lid 514 may generally cover the entirety of the first region 5011, without extending into a second region 5012 where a connector 502 is mounted.

Similarly, as shown in FIG. 6, two heat dissipation lids 615 are attached on an encapsulant layer of the electronic package 600 for heating dissipation. Under the two heat dissipation lids 615, two respective power circuit IC chips may be mounted on the substrate of the electronic package 600. The heat dissipation lids 615 can thus help dissipate heat generated from the IC chips thereunder. Furthermore, for some other small electronic components or low-power consumption IC chips which may not generate significant heat, no specific heat dissipation lid may be required.

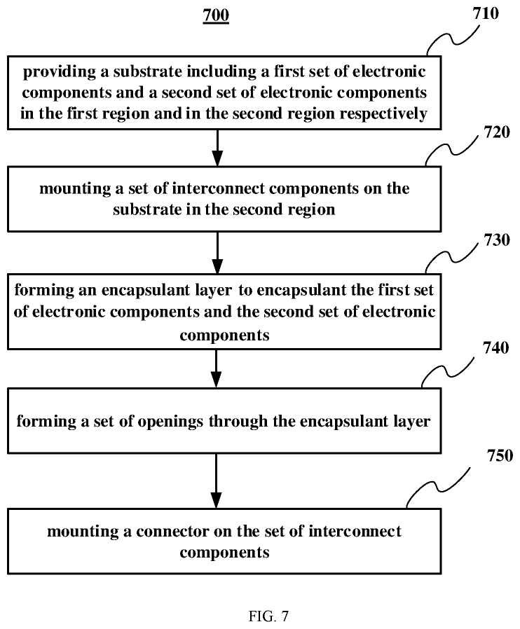

Referring to FIG. 7, a flowchart illustrating a method 700 for making an electronic package is illustrated according to an embodiment of the present application.

As illustrated in FIG. 7, the method 700 may begin with block 710, a substrate including a first set of electronic components and a second set of electronic components in the first region and in the second region respectively are provided. Then, at block 720, a set of interconnect components are mounted on the substrate in the second region. At block 730, an encapsulant layer is formed on the substrate to encapsulant the first set of electronic components and the second set of electronic components. At block 740, a set of openings through the encapsulant layer are formed to expose the set of interconnect components. At block 750, a connector is mounted on the interconnect components so that the connector is electrically coupled to the first and second set of electronic components through the set of interconnect components.

The discussion herein included numerous illustrative figures that showed various portions of an electronic package and a method for making the same. For illustrative clarity, such figures did not show all aspects of each example assembly. Any of the example devices and/or methods provided herein may share any or all characteristics with any or all other devices and/or methods provided herein. It could be understood that embodiments described in the context of one of the devices or methods are analogously valid for the other devices or methods. Similarly, embodiments described in the context of a device are analogously valid for a method, and vice versa. Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic package, comprising:
a substrate having a first region and a second region;
a first set of electronic components mounted on the substrate in the first region;
a second set of electronic components mounted on the substrate in the second region;
an encapsulant layer disposed on the substrate and encapsulating the first and second sets of electronic components;
a set of interconnect components disposed on the substrate in the second region, and extending through the encapsulant layer, wherein the set of interconnect components are electrically coupled to the first and second sets of electronic components; and
a connector mounted on the encapsulant layer and electrically coupled to the first and second sets of electronic components through the set of interconnect components.

2. The electronic package of claim 1, wherein a portion of the encapsulant layer in the first region is thicker than another portion of the encapsulant layer in the second region.

3. The electronic package of claim 1, wherein the set of interconnect components are disposed around the second set of electronic components.

4. The electronic package of claim 1, wherein the set of interconnect components are solder balls or conductive pillars.

5. The electronic package of claim 1, wherein the connector is a board-to-board connector.

6. The electronic package of claim 1, further comprising:
a shielding layer disposed over the encapsulant layer, wherein the set of interconnect components further extend through the shielding layer, and at least a portion of the set of interconnect components are not electrically connected to the shielding layer.

7. The electronic package of claim 6, further comprising:
a heat dissipation lid attached onto the shielding layer in the first region.

8. A method for making an electronic package, the method comprising:
providing a substrate having a first region and a second region;
mounting a first set of electronic components on the substrate in the first region;
mounting a second set of electronic components on the substrate in the second region;
mounting a set of interconnect components on the substrate in the second region;
forming an encapsulant layer on the substrate to encapsulate the first and second sets of electronic components and the set of interconnect components;
forming a set of openings through the encapsulant layer to expose the set of interconnect components; and
mounting a connector on the interconnect components, wherein the connector has a set of terminals that are aligned with the set of openings respectively, such that the connector is electrically coupled to the first and second sets of electronic components through the set of interconnect components.

9. The method of claim 8, wherein before forming a set of openings through the encapsulant layer, the method further comprises:
forming a shielding layer over the encapsulant layer, wherein at least a portion of the set of interconnect components are not electrically connected to the shielding layer.

10. The method of claim 9, further comprising:
attaching a heat dissipation lid onto the shielding layer in the first region.

11. The method of claim 8, wherein before mounting the connector on the encapsulant layer, the method further comprises:
filling within the set of openings respective conductive fillers to elevate the set of interconnect components to substantially above the encapsulant layer.

12. The method of claim 8, wherein a portion of the encapsulant layer in the first region is thicker than another portion of the encapsulant layer in the second region.

13. The method of claim 8, wherein the set of interconnect components are disposed around the second set of electronic components.

14. The method of claim 8, wherein the set of interconnect components are solder balls or conductive pillars.
